(19) United States
(12) Patent Application Publication
(10) Pub. No.: US 2026/0293117 A1
(43) Pub. Date: Sep. 24, 2026

(54) MEMORY DEVICE AND METHODS OF FABRICATING THE SAME

(71) Applicant: NANYA TECHNOLOGY CORPORATION, New Taipei City (TW)

(72) Inventor: Jung Tzu PENG, New Taipei City (TW)

(21) Appl. No.: 19/082,222

(22) Filed: Mar. 18, 2025

(51) Int. Cl. H10B 12/00

(52) U.S. Cl. CPC H10B 12/485; H10B 12/0335; H10B 12/053; H10B 12/34

(57) ABSTRACT

A memory device and its fabricating method are provided. The method includes forming a first word line (WL) nitride layer on an active area and a STI region, forming a WL mask layer on the first WL nitride layer, forming WL trenches extending through the WL mask layer, forming a WL metal layer and a second WL nitride layer in the WL trenches, removing the WL mask layer to form trenches, forming a bit line (BL) contact and a capacitor contact in the trenches, filling the trenches with a WL filling layer, forming a bit line on the BL contact through the WL filling layer, and forming a contact plug on the capacitor contact. The second WL nitride layer includes a first portion above a top surface of the first WL nitride layer and a second portion between the first portion and the WL metal layer.

### BACKGROUND

### Field of Invention

The present disclosure relates to the memory device and the fabrication method of the memory device.

### Description of Related Art

With the advancement of semiconductor techniques, the critical dimensions (CDs) of the semiconductor components in the memory device have become smaller, which has led to an increase in the component integration in the memory device. However, as the critical dimensions of the components get smaller, the semiconductor process techniques will face many challenges. For example, since the semiconductor components of the memory device have become smaller, it may be more difficult to achieve the alignment between the components on different layers of the memory device.

### SUMMARY

According to some embodiments of the present disclosure, a method of fabricating a memory device includes forming an active area and a shallow trench isolation (STI) region adjacent to the active area, forming a first word line nitride layer on the active area and the STI region, forming a word line mask layer on the first word line nitride layer, forming a plurality of word line trenches that extend into the active area and the STI region, and forming a word line metal layer and a second word line nitride layer in the word line trenches to form a plurality of word lines. The second word line nitride layer includes a first portion above a top surface of the first word line nitride layer and a second portion between the first portion and the word line metal layer. The method further includes removing the word line mask layer to form a plurality of trenches between the word lines, extending the trenches into the active area and the STI region, forming a bit line contact and a capacitor contact in the trenches, filling the trenches with a word line filling layer, forming a bit line on the bit line contact through the word line filling layer, and forming a contact plug on the capacitor contact.

According to some embodiments of the present disclosure, a memory device includes an active area and a STI region above a substrate, a first word line nitride layer on the active area and the STI region, a first word line extending into the active area, and a second word line extending into the STI region. Each of the first word line and the second word line includes a word line metal layer and a second word line nitride layer on the word line metal layer, and the second word line nitride layer comprises a first portion above a top surface of the first word line nitride layer and a second portion between the first portion and the word line metal layer. The memory device further includes an etch stop layer on the first word line nitride layer and the active area, a bit line connected to a bit line contact in the active area, and a contact plug connected to a capacitor contact in the active area.

According to the above-mentioned embodiments, the method of fabricating the memory device includes forming word lines in the word line trenches through the word line mask layer, and forming the bit line contacts and the capacitor contacts in the trenches between the word lines. The pattern of the word line mask layer defines the patterns of the word lines, the bit line contacts and the capacitor contacts, which reduces the number of masks used in the process, improves the critical dimension accuracy, and improves the alignment between those components in the memory device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a flow chart of an example method of memory device fabrication, according to some embodiments of the present disclosure.

FIGS. 2A and 8B illustrate schematic top views of a memory device at various stages of fabrication, according to some embodiments of the present disclosure.

FIGS. 2B-2C, 3-7, 8A, 9A-9B, and 10-13 illustrate schematic cross-sectional views of a memory device at various stages of fabrication, according to some embodiments of the present disclosure.

### DETAILED DESCRIPTION

The following disclosure provides many different embodiments, or examples, for implementing different features of the provided subject matter. Specific examples of components, arrangements, etc., are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

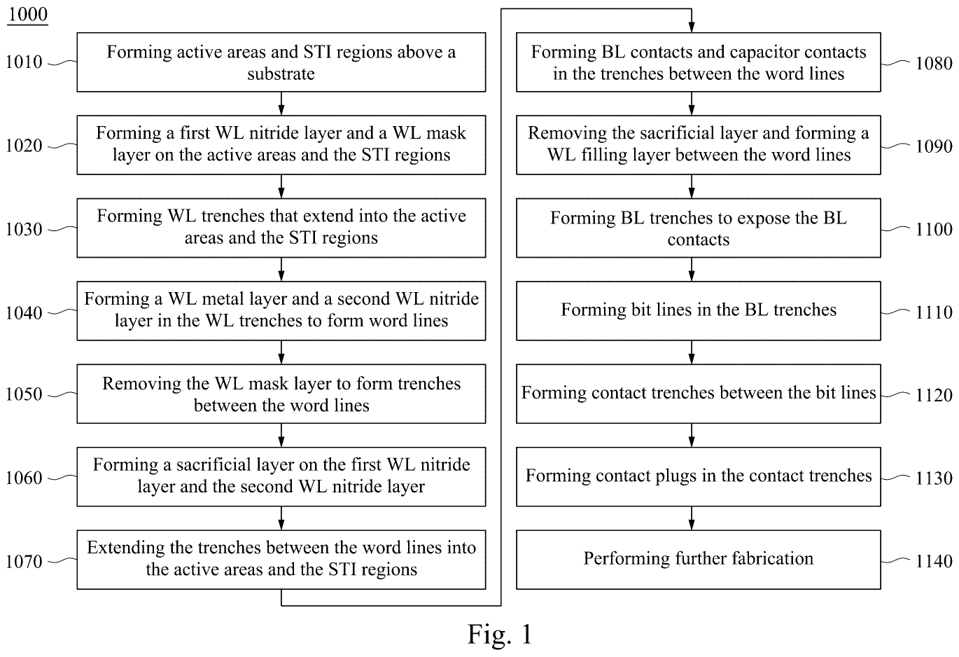

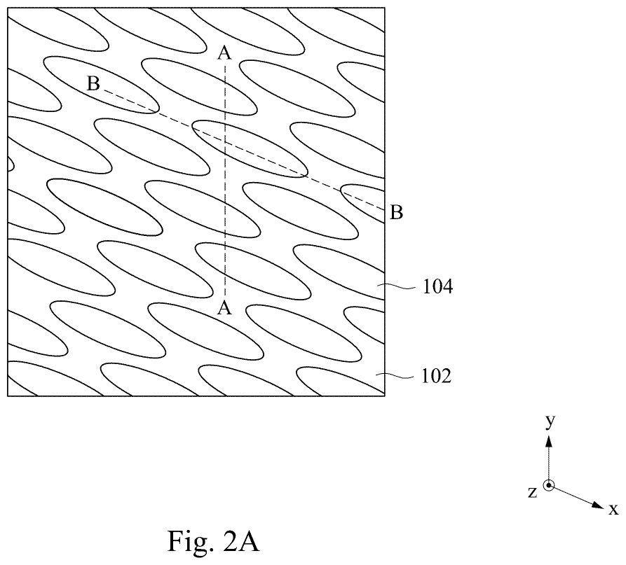

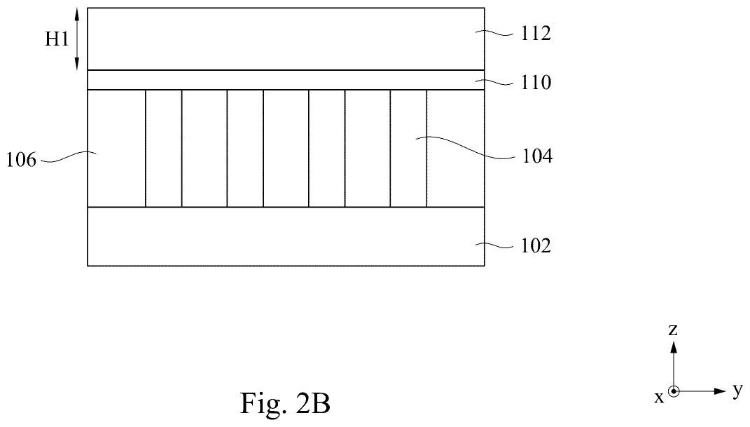

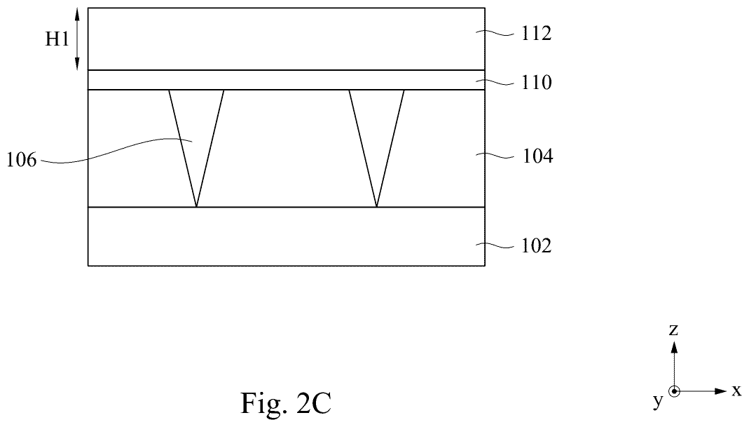

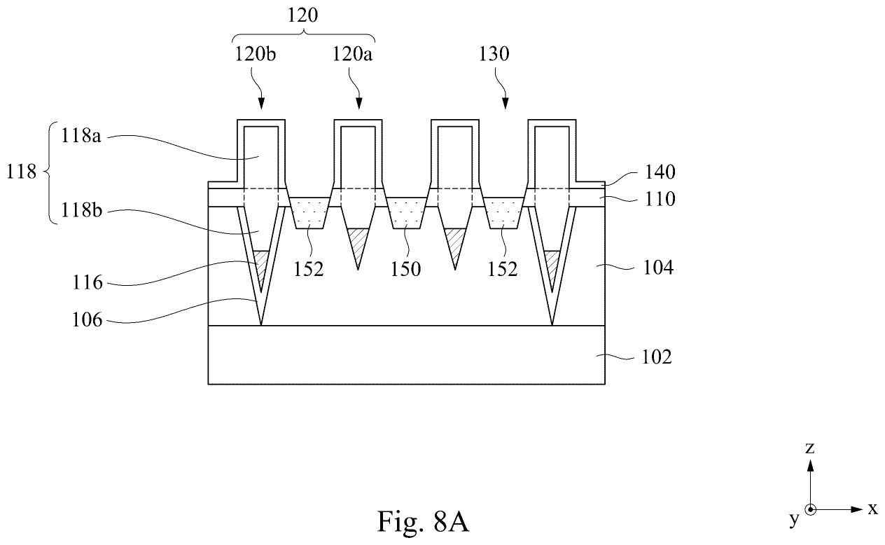

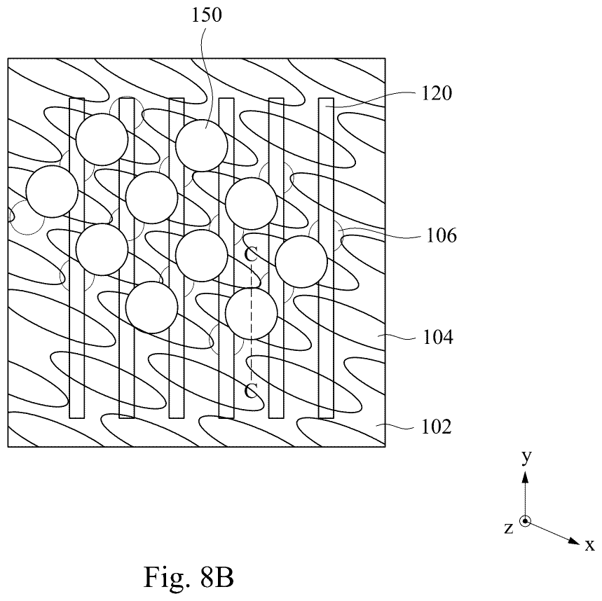

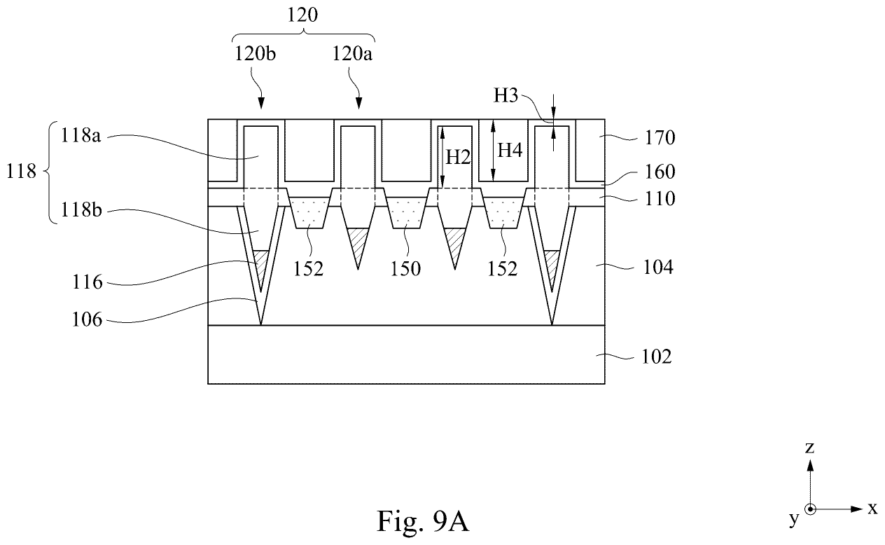

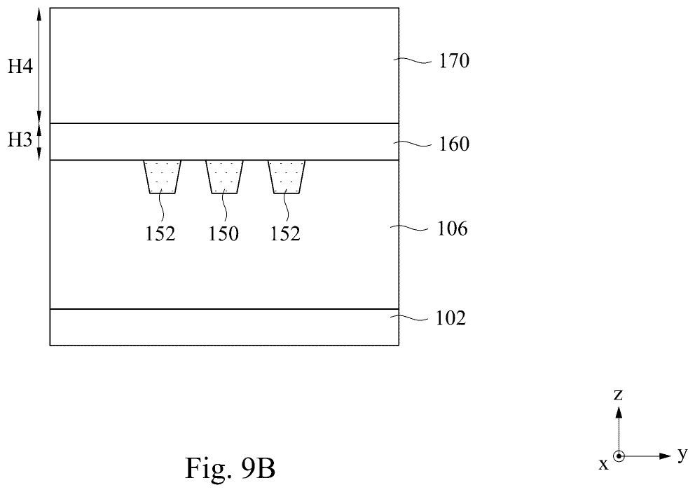

FIG. 1 illustrates a flow chart depicting an example method 1000 of memory device fabrication, according to various embodiments of the present disclosure. FIG. 1 will be described in conjunction with FIGS. 2A-2C, 3-7, 8A-8B, 9A-9B, and 10-13, where FIGS. 2A and 8B illustrate schematic top views of a memory device 100 at various stages of fabrication, FIG. 2B illustrates a schematic cross-sectional view of the memory device 100 along the line A-A in FIG. 2A, FIGS. 2C, 3-7, 8A, and 9A illustrate schematic cross-sectional views of the memory device 100 at various stages of fabrication along the line B-B in FIG. 2A, and FIGS. 9B and 10-13 illustrate schematic cross-sectional views of the memory device 100 at various stages of fabrication along the line C-C in FIG. 8B, according to some embodiments of the present disclosure.

The method 1000 is merely an example; additional steps may be provided before, during, and after the method 1000, and some of the steps described can be moved, replaced, or eliminated for additional embodiments of the method 1000. Additional features may be added in the memory device 100 depicted in the figures, and some of the features described below can be replaced, modified, or eliminated in other embodiments.

At block 1010, the method 1000 includes forming active areas and shallow trench isolation (STI) regions above a substrate. Referring to FIGS. 2A-2C, in an embodiment of block 1010, a substrate 102 is provided for forming the memory device 100. In some embodiments, the substrate 102 may be a semiconductor substrate, such as a silicon (Si) substrate. The substrate 102 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 102 may include a compound semiconductor and/or an alloy semiconductor.

A plurality of active areas 104 are formed above the substrate 102. The active areas 104 are separated from each other to serve as channel regions for memory cells in the memory device 100. For example, as shown in FIG. 2A, the active areas 104 may have island patterns in the top view. However, other embodiments are possible including those that provide for the active areas having different patterns. In some embodiments, the active areas 104 may be formed of silicon-containing material, such as Si or SiGe. The active areas 104 may include various doping configurations depending on device requirements. The active areas 104 may be formed by depositing a silicon-containing layer on the substrate 102, followed by an etching process to pattern the silicon-containing layer into the active areas 104.

STI regions 106 are formed above the substrate 102 and adjacent to the active areas 104, where one of the active areas 104 is sandwiched by two of the STI regions 106. The sidewalls of the STI regions 106 may directly contact the sidewalls of the active areas 104, so that the profiles of the STI regions 106 relates to the profiles of the active areas 104. For example, as shown in FIG. 2C, the width of the STI regions 106 along the x-axis direction may decrease toward the substrate 102, while the width of the active areas 104 correspondingly increases toward the substrate 102. In some embodiments, the STI regions 106 may be formed of an oxide, such as SiOₓ. The STI regions 106 may be formed by filling the gaps between the active areas 104 with the oxide material. After the formation of the active areas 104 and the STI regions 106, an annealing process and a planarization process, such as chemical mechanical polishing (CMP), may be performed before forming other components onto the active areas 104.

At block 1020, the method 1000 includes forming a first word line (WL) nitride layer and a word line mask layer on the active areas and the STI regions. Referring to FIGS. 2B-2C, in an embodiment of block 1020, a first word line nitride layer 110 is formed on the active areas 104 and the STI regions 106 to cover the top surfaces of the active areas 104 and the STI regions 106. A word line mask layer 112 is then formed on the top surface of the first word line nitride layer 110. In some embodiments, the first word line nitride layer 110 may be formed of a nitride, such as SiN, deposited by chemical vapor deposition (CVD), physical vapor deposition (PVD), atomic layer deposition (ALD), or the like. The word line mask layer 112 may be formed by deposition or spin-coating a hard mask material with a thickness H1 along the z-axis direction. It should be noted that the thickness H1 of the word line mask layer 112 relates to the height of the later-formed bit line (BL) structure, which will be discussed in detail below.

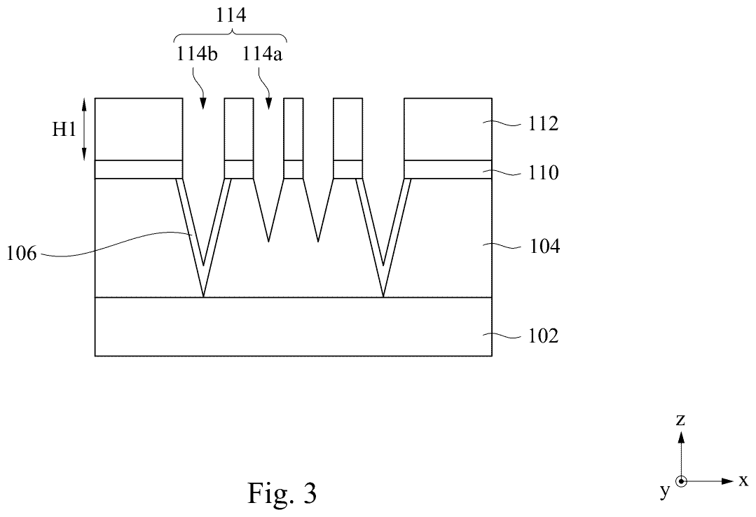

At block 1030, the method 1000 includes forming word line trenches that extend into the active areas and the STI regions. Referring to FIG. 3, in an embodiment of block 1030, a plurality of word line trenches 114 are formed though the word line mask layer 112, through the first word line nitride layer 110, and into the active areas 104 or the STI regions 106. Specifically, in the cross-sectional view, the word line trenches 114 may include word line trenches 114a extending into the active areas 104 with a smaller depth and word line trenches 114b extending into the STI regions 106 with a larger depth. It should be noted that one of the word line trenches 114 may be a word line trench 114a for one active area 104 in one cross-sectional view but a word line trench 114b for one STI region 106 in another cross-sectional view.

The word line trenches 114b may be formed along the sidewalls of the STI regions 106, so that the STI regions 106 remained in the word line trenches 114b have a uniform thickness. The word line trenches 114a and the word line trenches 114b are formed in the same process, so the profile of the word line trenches 114a may be similar to the profile of the word line trenches 114b. Depending on the process used for forming the word line trenches 114, the width of the word line trenches 114 in the active areas 104 or the STI regions 106 along the x-axis direction may decrease toward the substrate 102. In some embodiments, the word line trenches 114 may be formed by patterning a photoresist (not shown) on the word line mask layer 112 to form openings that expose the top surface of the word line mask layer 112, followed by etching the word line mask layer 112, the first word line nitride layer 110, the active areas 104, and the STI regions 106 through the openings in the photoresist. The patterning process and the etching process may be combined as a self-aligned double patterning (SADP) process.

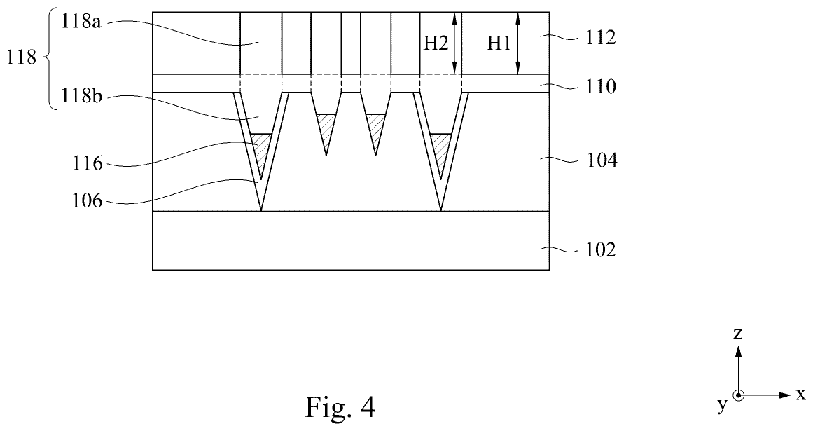

At block 1040, the method 1000 includes forming a word line metal layer and a second word line nitride layer in the word line trenches to form word lines. Referring to FIG. 4, in an embodiment of block 1040, a word line metal layer 116 is formed in the bottom portion of the word line trenches 114 in FIG. 3. In some embodiments, the word line trenches 114 may first be filled with the word line metal layer 116 by any suitable process, such as atomic layer deposition, sputtering, plating, and/or combinations thereof, followed by an etching back process onto the word line metal layer 116 until the top surface of the word line metal layer 116 is lower than the top surfaces of the active areas 104. A dielectric layer, such as an oxide layer, may be deposited in the word line trenches 114 before forming the word line metal layer 116, so that the word line metal layer 116 and the active areas 104 (or the STI regions 106) are separated by the dielectric layer.

A second word line nitride layer 118 is then formed in the word line trenches 114 above the word line metal layer 116. The second word line nitride layer 118 fills the remained portion of the word line trenches 114, so that the top surface of the second word line nitride layer 118 is levelled with the top surface of the word line mask layer 112. As a result, the second word line nitride layer 118 includes a first portion 118a above the top surface of the first word line nitride layer 110 and a second portion 118b between the first portion 118a and the word line metal layer 116. A height H2 of the first portion 118a along the z-axis direction equals to the thickness H1 of the word line mask layer 112.

In some embodiments, the second word line nitride layer 118 may be formed of a nitride material same as the first word line nitride layer 110, such as SiN. In such embodiments, when the second word line nitride layer 118 is formed in the word line trenches 114, the second word line nitride layer 118 may direct contact the first word line nitride layer 110 without forming an observable interface between the first word line nitride layer 110 and the second word line nitride layer 118. The second word line nitride layer 118 may be deposited in the word line trenches 114 by chemical vapor deposition, physical vapor deposition, atomic layer deposition, or other suitable deposition process, followed by a planarization process or an etching back process onto the second word line nitride layer 118 to form the coplanar top surfaces of the second word line nitride layer 118 and the word line mask layer 112.

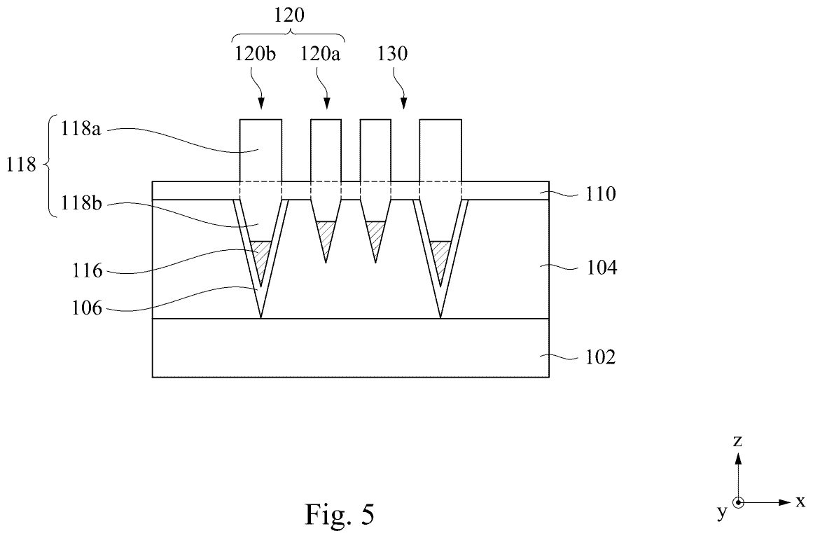

At block 1050, the method 1000 includes removing the word line mask layer to form trenches between the word lines. Referring to FIG. 5, in an embodiment of block 1050, the word line mask layer 112 in FIG. 4 is removed from the first word line nitride layer 110 by a wet etching process or a wet stripping process, leaving the trenches 130 above the first word line nitride layer 110 and between the first portions 118a of the second word line nitride layer 118. As a result, the word lines 120 including the word line metal layer 116 and the second word line nitride layer 118 are formed with strip patterns in the top view (as shown in FIG. 8B), where the first portions 118a of the word lines 120 are separated by the trenches 130. In the cross-sectional view, the word lines 120 include the word lines 120a extending into the active areas 104 and the word lines 120b extending into the STI regions 106, where the second word line nitride layer 118 of the word lines 120a and the word lines 120b are connected by the first word line nitride layer 110. It should be noted that one of the word lines 120 may be a word line 120a for one active area 104 in one cross-sectional view but a word line 120b for one STI region 106 in another cross-sectional view. The pattern and the height H2 of the word lines 120 relate to the pattern and height of the later-formed bit line structure, which will be discussed in detail below.

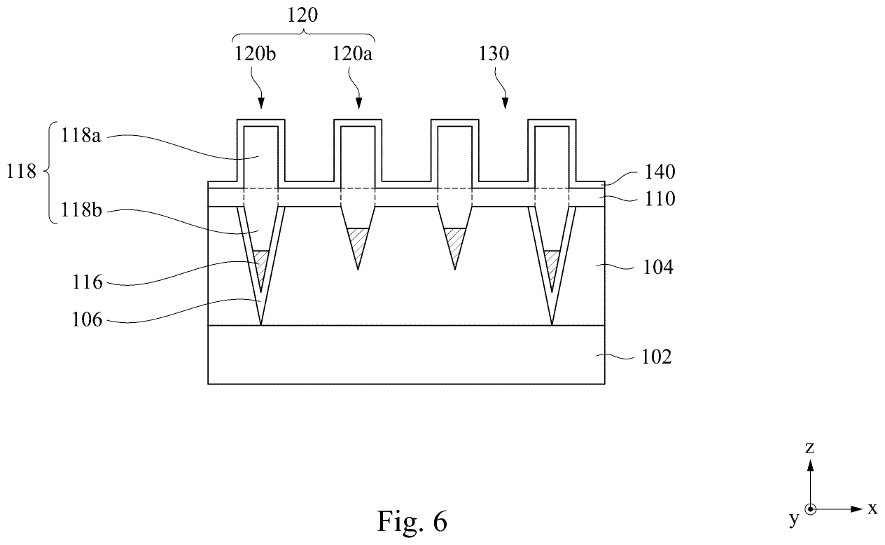

At block 1060, the method 1000 includes forming a sacrificial layer on the first word line nitride layer and the second word line nitride layer. Referring to FIG. 6, in an embodiment of block 1060, a sacrificial layer 140 is formed on the top surface of the first word line nitride layer 110 and the sidewalls and the top surface of the first portion 118a of the second word line nitride layer 118. The sacrificial layer 140 is formed with a thin thickness, so that a portion of each of the trenches 130 remains between the word lines 120. In some embodiments, the sacrificial layer 140 may be an oxide material, such as SiOₓ, formed by a highly conformal deposition process, such as atomic layer deposition.

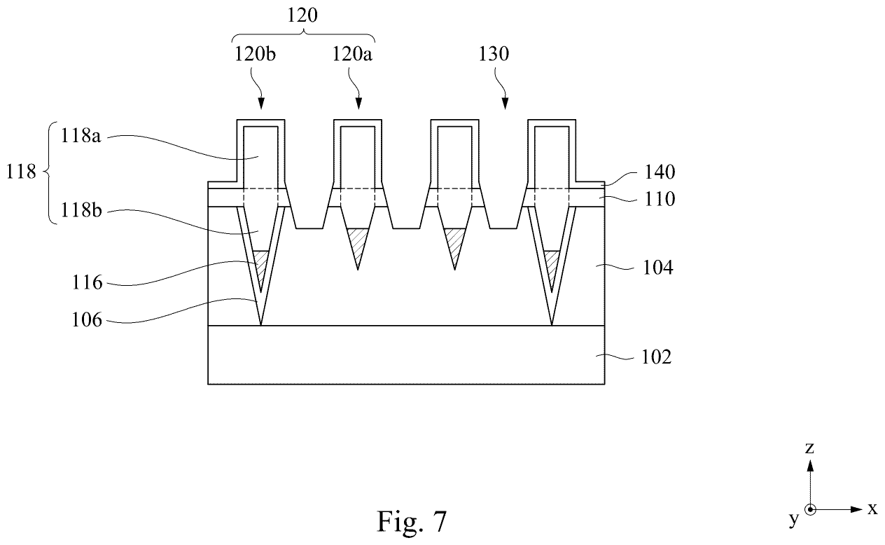

At block 1070, the method 1000 includes extending the trenches between the word lines into the active areas and the STI regions. Referring to FIG. 7, in an embodiment of block 1070, an etching process is performed on the sacrificial layer 140 at the bottom surface of the trenches 130, which extends the trenches 130 downward through the sacrificial layer 140 and the first word line nitride layer 110. The bottom surfaces of the trenches 130 stop in the active areas 104 (as shown in FIG. 7) or the STI regions 106 (referring to the bit line contacts 150 and capacitor contacts 152 in FIG. 9B). The etching process extends the trenches 130 along the sidewalls of the sacrificial layer 140 on the sidewalls of the trenches 130, where a portion of the sacrificial layer 140 remain on the sidewalls of the trenches 130 after extending the trenches 130. As a result, the width of the trenches 130 in the active areas 104 along the x-axis direction depends on the thickness of the sacrificial layer 140 on the sidewalls of the trenches 130.

In some embodiments, the etching process may be an anisotropic dry etching process. The etching process may be performed in multi-steps by changing the composition and the flow of the etching gas, where the material loss of the active areas 104 may be well controlled. For example, the sacrificial layer 140, the first word line nitride layer 110, and the active areas 104 may be sequentially etched by a first etching gas, a second etching gas different from the first etching gas, and a third etching gas different from the first etching gas and the second etching gas, respectively. The STI regions 106 surrounding the word line metal layer 116 may remain un-etched during the etching process of the trenches 130, which protects the word line metal layer 116 from being exposed in the trenches 130.

At block 1080, the method 1000 includes forming bit line contacts and capacitor contacts in the trenches between the word lines. Referring to FIGS. 8A-8B, in an embodiment of block 1080, each of bit line contacts 150 and capacitor contacts 152 are formed in the trench 130 between two adjacent one of the word lines 120. Specifically, in the cross-sectional view, the bit line contact 150 is formed in the bottom portion of the trench 130 between two of the word lines 120a, and the capacitor contact 152 is formed in the bottom portion of the trench 130 between the word line 120a and the word line 120b.

The pattern of the bit line contacts 150 and the capacitor contacts 152 are formed based on the pattern of the trenches 130 between the word lines 120, where the pattern of the trenches 130 (or the word lines 120) are formed based on the pattern of the word line mask layer 112. In other words, the pattern of the word line mask layer 112 defines the patterns of the word lines 120, the bit line contacts 150, and the capacitor contacts 152. As a result, the word line mask layer 112 reduces the number of masks used in the process for forming the memory device 100. The usage of the word line mask layer 112 also improves the critical dimension accuracy of and the x-axis direction (or the y-axis direction) alignment between the word lines 120, the bit line contacts 150, and the capacitor contacts 152. Specifically, the bit line contacts 150 are formed according to the pattern of the trenches 130 between the word lines 120, so that the self-aligned bit line contacts 150 and the word lines 120 may reduce the overlay of the bit line contacts 150 on the word lines 120. Similarly, the capacitor contacts 152 and the word lines 120 are also self-aligned, so that the capacitor contacts 152 may be formed with uniform contact areas.

The thicknesses of the bit line contacts 150 and the capacitor contacts 152 along the z-axis direction are controlled to form the top surfaces of the bit line contacts 150 and the capacitor contacts 152 higher than or levelled with a middle position of the first word line nitride layer 110. In other words, a distance between the top surface of the bit line contact 150 (or the capacitor contact 152) and the top surface of the first word line nitride layer 110 is smaller than or equal to half of a thickness of the first word line nitride layer 110, which may reduce the leakage occurring between the word lines 120. In some embodiments, the top surfaces of the bit line contacts 150 and the capacitor contacts 152 is lower than or levelled with the top surface of the first word line nitride layer 110. In addition, the widths of the bit line contacts 150 and the capacitor contacts 152 along the x-axis direction depend on the width of the trenches 130 with the sacrificial layer 140 on its sidewalls. As a result, the critical dimensions of the bit line contact 150 and the capacitor contact 152 may be controlled by the thickness of the sacrificial layer 140 deposited on the sidewalls of the trenches 130.

In some embodiments, the bit line contacts 150 and the capacitor contacts 152 may be formed by filling the trenches 130 with a conductive material, such as polysilicon, by a deposition process. The conductive material in the trenches 130 are etched back until the top surfaces of the bit line contacts 150 and the capacitor contacts 152 are lower than or levelled with the top surface of the first word line nitride layer 110. To adjust the resistance of the bit line contacts 150 and the capacitor contacts 152, the conductive material of the bit line contacts 150 and the capacitor contacts 152 may be implanted by a dopant, or a silicide layer may be formed on the conductive material of the bit line contacts 150 and the capacitor contacts 152.

At block 1090, the method 1000 includes removing the sacrificial layer and forming a word line filling layer between the word lines. Referring to FIGS. 9A-9B, in an embodiment of block 1090, the sacrificial layer 140 is removed from the word lines 120, for example, by an etching process, which re-exposes the first word line nitride layer 110 and the second word line nitride layer 118. An etch stop layer 160 is formed to cover the first word line nitride layer 110, the second word line nitride layer 118, the bit line contacts 150, and the capacitor contacts 152. The etch stop layer 160 is formed with a thin thickness, so that a portion of each of the trenches 130 remains between the word lines 120. In some embodiments, the etch stop layer 160 may be formed of a nitride, such as SiN, with a thickness H3 along the z-axis direction. The etch stop layer 160 may be formed by a highly conformal deposition, such as atomic layer deposition, to conformally cover the top surface of first word line nitride layer 110, the sidewalls and top surface of the second word line nitride layer 118, the top surface of the bit line contact 150, and the top surface of the capacitor contact 152.

A word line filling layer 170 is then formed to fill the remained portion of the trenches 130. After the formation of the word line filling layer 170, the top surface of the etch stop layer 160 on the second word line nitride layer 118 is levelled with the top surface of the word line filling layer 170. In some embodiments, the word line filling layer 170 may be formed of a dielectric material different from the material of the etch stop layer 160. For example, the word line filling layer 170 may be formed of an oxide, while the etch stop layer 160 is formed of a nitride. The word line filling layer 170 may be formed by a spin-on coating process, followed by a planarization process or an etching back process that stops on the top surface of the etch stop layer 160. As a result, a thickness H4 of the word line filling layer 170 along the z-axis direction equals to the height H2 of the first portions 118a of the second word line nitride layer 118.

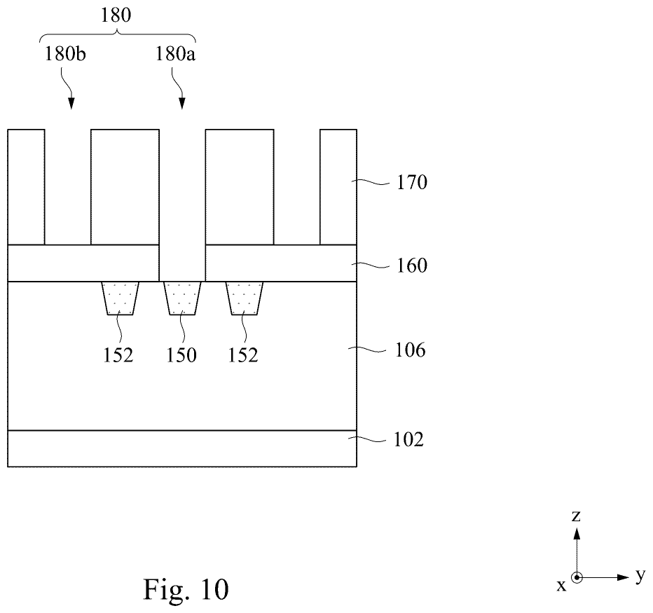

At block 1100, the method 1000 includes forming bit line trenches to expose the bit line contacts. Referring to FIG. 10, in an embodiment of block 1100, bit line trenches 180 are formed by etching through the word line filling layer 170. The width of the bit line trenches 180 along the y-axis direction corresponds to the critical dimensions of the later-formed bit line spacer and bit line. Specifically, in the cross-sectional view, the bit line trench 180a is formed above the bit line contact 150, and the bit line trenches 180b are form in the word line filling layer 170 near the capacitor contact 152. For the bit line trench 180 above the bit line contact 150, the word line filling layer 170 and the etch stop layer 160 are etched through to expose the top surface of the bit line contact 150. The etching process may stop on the top surface of the bit line contact 150, or the bit line contacts may be over-etched to form the top surface of the bit line contact 150 lower than the bottom surface of the etch stop layer 160. For the bit line trench 180 above the capacitor contact 152, the etching process of the bit line trench 180 etches through the word line filling layer 170 and stops on the top surface of the etch stop layer 160 or the first word line nitride layer 110. The STI regions 106 may remain un-etched during the etching process for the bit line trenches 180. It should be noted that the bit line trench 180 above the capacitor contact 152 in one cross-sectional view may be the bit line trench 180 above the bit line contact 150 in another cross-sectional view.

In some embodiments, the bit line trenches 180 may be formed by forming a bit line mask layer (not shown) on the word line filling layer 170, patterning the bit line mask layer to form the openings in the bit line mask layer, and etching the word line filling layer 170 and/or the etch stop layer 160 through the openings in the bit line mask layer. The patterning process and the etching process may be combined as a self-aligned double patterning (SADP) process.

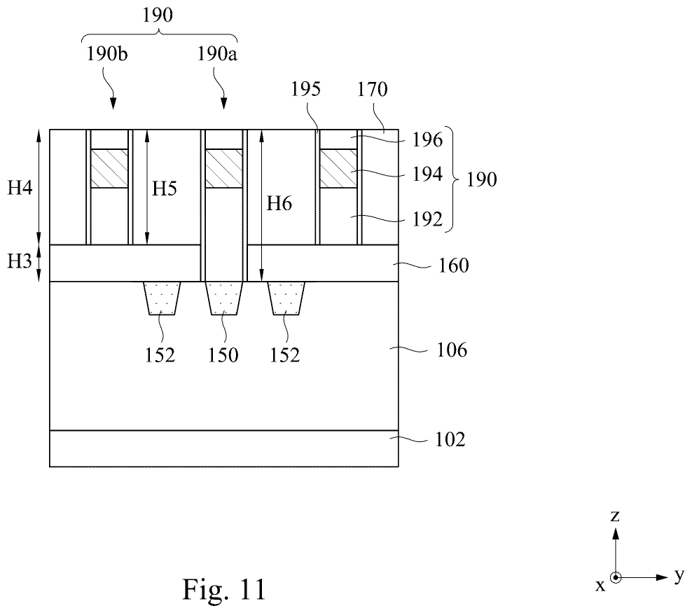

At block 1110, the method 1000 includes forming bit lines in the bit line trenches. Referring to FIG. 11, in an embodiment of block 1110, bit line spacers 195 are first formed on the sidewalls of the bit line trenches 180. The bit line spacers 195 are formed with a thin thickness, so that a portion of each of the bit line trenches 180 remains above the bit line contact 150 or the capacitor contact 152. In some embodiments, the bit line spacers 195 may be formed as a multi-layer of low-k dielectric materials, such as a nitride-oxide-nitride layer. The bit line spacers 195 may be formed by depositing the dielectric material in the bit line trenches 180, for example, by atomic layer deposition or other highly conformal deposition process. The dielectric material at the bottom surface of the bit line trenches 180 is then removed by an etching process to re-expose the bit line contact 150, where the dielectric layer of the bit line spacers 195 deposited on the word line filling layer 170 may also be removed by the same etching process.

After forming the bit line spacers 195, a bit line polysilicon layer 192, a bit line metal layer 194, and a bit line nitride layer 196 are sequentially formed in the bit line trenches 180 to form the bit line 190 between the bit line spacers 195, where the bit line polysilicon layer 192 is in contact with the bit line contacts 150. Since the bit line spacers 195 are formed before the bit line polysilicon layer 192 and the bit line metal layer 194, the formation of the bit lines 190 may be referred to as a reverse bit line process. After the formation of the bit lines 190, the word lines 120 may extend along a first direction while the bit lines 190 extend along a second direction perpendicular to the first direction.

In some embodiments, the bit lines 190 may be formed by filling the bit line trenches 180 with the bit line polysilicon layer 192, etching back the bit line polysilicon layer 192 to a predefined thickness, filling the bit line trenches 180 with the bit line metal layer 194, etching back the bit line metal layer 194 to a predefined thickness, depositing the bit line nitride layer 196 in the bit line trenches 180 and on the word line filling layer 170, and performing a planarization process or an etching back process on the bit line nitride layer 196 to form the top surfaces of the bit lines 190 coplanar with the top surface of the word line filling layer 170.

The top surface of the topmost layer of the bit line 190, such as the bit line nitride layer 196, is levelled with the top surface of the bit line spacers 195 and the top surface of the word line filling layer 170. In the cross-sectional view, the height H5 of the bit line 190a on the bit line contact 150 along the z-axis direction equals to a sum of the thickness H3 of the etch stop layer 160 and the thickness H4 of the word line filling layer 170, and the height H6 of the bit line 190b above the capacitor contact 152 along the z-axis direction equals to the thickness H4 of the word line filling layer 170. As mentioned above, the thickness H4 may equal to the height H2 of the first portions 118a of the second word line nitride layer 118 (as shown in FIG. 9A), where the height H2 of the first portion 118a equals to the thickness H1 of the word line mask layer 112 (as shown in FIG. 4). In other words, the thickness H1 of the word line mask layer 112 may define the height of the bit line 190.

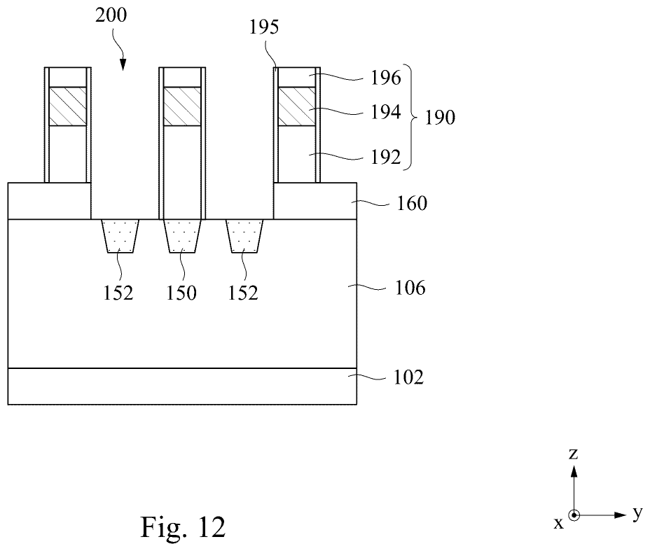

At block 1120, the method 1000 includes forming contact trenches between the bit lines. Referring to FIG. 12, in an embodiment of block 1120, the word line filling layer 170 is removed from the etch stop layer 160 by an etching process, such as a wet etching process. The etch stop layer 160 on the capacitor contact 152 and between the bit lines 190 is punched through to form contact trenches 200 exposing at least a portion of the top surface of the capacitor contact 152. The etch stop layer 160 may be punched through along the sidewalls of the bit line spacers 195. In some embodiments, a cleaning process may be performed after the formation of the contact trenches 200 to remove possible contamination from the punch-through process.

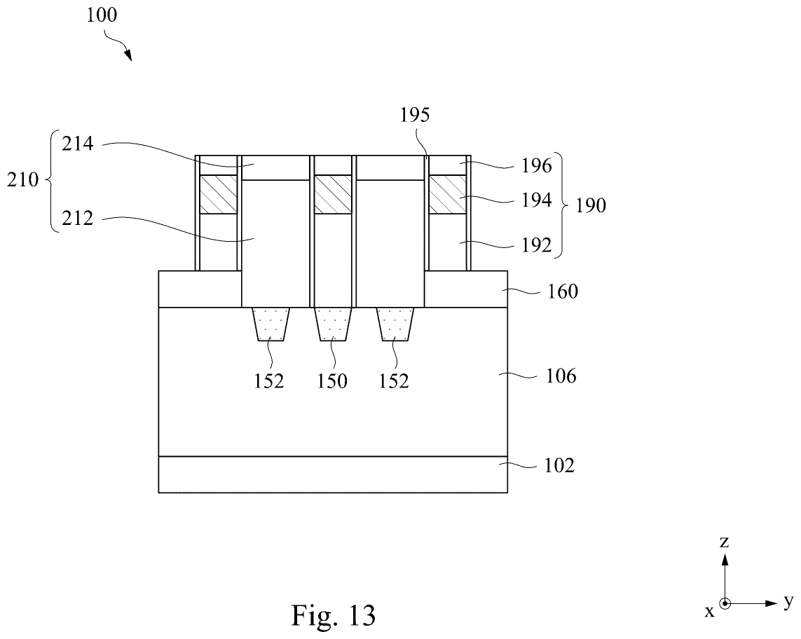

At block 1130, the method 1000 includes forming contact plugs in the contact trenches. Referring to FIG. 13, in an embodiment of block 1130, contact plugs 210 are formed in the contact trenches 200 in FIG. 12. The contact plugs 210 are in contact with the capacitor contacts 152 and may be further connected to the capacitors above the contact plugs 210. In some embodiments, the contact plugs 210 may be formed by filling the contact trenches 200 with a polysilicon layer 212 by a deposition process, etching back the polysilicon layer 212 to a predefined thickness, filling the contact trenches 200 with a contact metal layer 214, and performing a planarization process or an etching back process on the contact metal layer 214 to form the top surfaces of the contact plugs 210 coplanar with the top surface of the bit lines 190. To adjust the resistance of the contact plugs 210, the polysilicon layer 212 may be implanted by a dopant, or a silicide layer may be formed on the capacitor contacts 152 or the polysilicon layer 212.

At block 1140, the method 1000 includes performing further fabrication. A memory device, such as memory device 100 in FIG. 13, may undergo further processing to form various features and regions known in the art. For example, subsequent processing may form capacitors, as well as various contacts/vias/lines and multilayer interconnect features (e.g., metal layers and interlayer dielectrics) above the substrate, configured to connect the various features to form a functional circuit. Moreover, additional process steps may be implemented before, during, and after the method 1000, and some process steps described above may be replaced or eliminated in accordance with various embodiments of the method 1000.

According to the above-mentioned embodiments, the method of fabricating the memory device of the present disclosure includes forming word lines by depositing the second word line nitride layer in the word line trenches through the word line mask layer and the first word line nitride layer, and forming the bit line contacts and the capacitor contacts in the trenches between the word lines. The pattern of the word line mask layer defines the patterns of the word lines, the bit line contacts and the capacitor contacts, which reduces the number of masks used in the process for forming the memory device. This also improves the critical dimension accuracy of and the alignment between the word lines, the bit line contacts and the capacitor contacts.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a memory device, comprising:
forming an active area and a shallow trench isolation (STI) region adjacent to the active area;
forming a first word line nitride layer on the active area and the STI region;
forming a word line mask layer on the first word line nitride layer;
forming a plurality of word line trenches that extend through the word line mask layer into the active area and the STI region;
forming a word line metal layer and a second word line nitride layer in the word line trenches to form a plurality of word lines, wherein the second word line nitride layer comprises a first portion above a top surface of the first word line nitride layer and a second portion between the first portion and the word line metal layer;
removing the word line mask layer to form a plurality of trenches between the word lines;
extending the trenches into the active area and the STI region;
forming a bit line contact and a capacitor contact in the trenches;
filling the trenches with a word line filling layer;
forming a bit line on the bit line contact through the word line filling layer; and
forming a contact plug on the capacitor contact.

2. The method of claim 1, wherein a thickness of the word line mask layer equals to a height of the first portion of the second word line nitride layer.

3. The method of claim 1, wherein a thickness of the word line filling layer equals to a height of the first portion of the second word line nitride layer.

4. The method of claim 1, wherein a top surface of the second word line nitride layer is levelled with a top surface of the word line mask layer after forming the second word line nitride layer in the word line trenches.

5. The method of claim 1, wherein a distance between a top surface of the bit line contact and the top surface of the first word line nitride layer is smaller than or equal to half of a thickness of the first word line nitride layer.

6. The method of claim 1, further comprising:
forming a bit line trench through the word line filling layer to expose the bit line contact;
forming a plurality of bit line spacers on sidewalls of the bit line trench; and
filling the bit line trench with a bit line polysilicon layer, a bit line metal layer on the bit line polysilicon layer, and a bit line nitride layer on the bit line metal layer.

7. The method of claim 6, wherein a height of the bit line equals to a sum of a thickness of the word line filling layer and a thickness of an etch stop layer below the word line filling layer.

8. The method of claim 1, further comprising:
forming an etch stop layer to cover the first word line nitride layer, the second word line nitride layer, the bit line contact, and the capacitor contact; and
forming the word line filling layer on the etch stop layer in the trenches, wherein a top surface of the etch stop layer on the second word line nitride layer is levelled with a top surface of the word line filling layer.

9. The method of claim 8, further comprising:
removing the word line filling layer;
performing a punch-through process on the etch stop layer to form a contact trench that expose the capacitor contact; and
forming the contact plug in the contact trench.

10. The method of claim 1, further comprising:
forming a sacrificial layer on the first word line nitride layer and the second word line nitride layer; and
performing an etching process on the sacrificial layer at bottom surfaces of the trenches to extend the trenches through the sacrificial layer and the first word line nitride layer and into the active area and the STI region, wherein a portion of the sacrificial layer remains on sidewalls of the trenches after the etching process.

11. The method of claim 10, wherein the sacrificial layer is removed after forming the bit line contact and the capacitor contact and before forming the word line filling layer.

12. The method of claim 10, wherein the etching process comprises:
etching the sacrificial layer by a first etching gas;
etching the first word line nitride layer by a second etching gas; and
etching the active area by a third etching gas, wherein the first etching gas, the second etching gas, and the third etching gas are different from each other.

13. The method of claim 1, further comprising:
implanting the bit line contact and the capacitor contact before forming the word line filling layer; or
forming a silicide layer the bit line contact and the capacitor contact before forming the word line filling layer.

14. The method of claim 1, wherein forming the word line trenches comprises:
patterning a photoresist on the word line mask layer to form a plurality of openings that expose the word line mask layer; and
etching the word line mask layer, the first word line nitride layer, the active area, and the STI region through the openings in the photoresist.

15. The method of claim 1, wherein one of the word line trenches that extends into the active area has a smaller depth than another one of the word line trenches that extends into the STI region.

16. A memory device, comprising:
an active area and a STI region above a substrate;
a first word line nitride layer on the active area and the STI region;
a first word line extending into the active area and a second word line extending into the STI region,
wherein each of the first word line and the second word line comprises a word line metal layer and a second word line nitride layer on the word line metal layer, and the second word line nitride layer comprises a first portion above a top surface of the first word line nitride layer and a second portion between the first portion and the word line metal layer;
an etch stop layer on the first word line nitride layer and the active area;
a bit line connected to a bit line contact in the active area; and
a contact plug connected to a capacitor contact in the active area.

17. The memory device of claim 16, wherein a top surface of the bit line contact and a top surface of the capacitor contact are higher than or levelled with a middle position of the first word line nitride layer.

18. The memory device of claim 16, wherein a thickness of the bit line on the etch stop layer equals to a height of the first portion of the second word line nitride layer.

19. The memory device of claim 16, wherein the first word line nitride layer and the second word line nitride layer are formed of a same nitride material.

20. The memory device of claim 16, wherein a top surface of the word line metal layer is lower than a top surface of the active area.
